(19) United States
(12) Patent Application Publication
(10) Pub. No.: US 2012/0141837 A1
(43) Pub. Date: Jun. 7, 2012

(54) TETRAGONAL MANGANESE GALLIUM FILMS

(75) Inventors: Huseyin KURT, Dublin (IE); Karsten RODE, Dublin (IE); John Michael David COEY, Dublin (IE)

(73) Assignee: The Provost Fellows, Foundation Scholars, & Other Members of Board, of the College of the Holy & Und, Dublin (IE)

(21) Appl. No.: 13/308,986

(22) Filed: Dec. 1, 2011

Related U.S. Application Data
(60) Provisional application No. 61/418,484, filed on Dec. 1, 2010.

(30) Foreign Application Priority Data
Dec. 1, 2010 (GB) 1020308.1

(51) Int. Cl. G11B 5/65; C23C 14/14; C23C 14/34; G11B 5/84; C22C 23/00

(52) U.S. Cl. 428/832; 428/836.1; 427/128; 420/402; 204/192.1

(57) ABSTRACT

A magnetic recording medium for use in storing information is described, the medium comprising the use of a manganese-gallium alloy. More specifically, in one embodiment there is provided a magnetic recording medium comprising a substrate having a surface upon which is placed a magnetic recording layer, wherein the magnetic recording layer comprises a Manganese-Gallium alloy material with uniaxial anisotropy.

### FIELD OF THE INVENTION

The invention relates to a magnetic recording medium. More specifically, the invention relates to a bit patterned magnetic recording medium comprising thin material films and methods for producing the same.

### BACKGROUND TO THE INVENTION

The density of information recorded on hard disks has been doubling, on average, every year since the introduction of the magneto-resistive read heads in 1991. Continuously growing demand for high density data storage led to a major change in technology from in-plane to perpendicular recording at the beginning of 2005. This was realized through the use of uniaxial magnetic materials which exhibit perpendicular anisotropy such as Cobalt-Chromium-Platinum (CoCrPt) alloys. As the dimensions of the recorded bits decrease, neighbouring magnetic domains can demagnetize each other, placing an upper limit on areal density in continuous perpendicular media, which is 1 Tb/inch² (1500 b μm⁻²).

Bit patterned media (BPM), which utilize individual magnetic nano islands with perpendicular anisotropy offer a way forward. Areal densities beyond 1 Tb/inch² require magnetic materials with very high uniaxial anisotropy for increased thermal stability at the reduced dimensions desirable by industry. Potential materials for BPM are L1₀-CoPt or FePt compounds, which can theoretically support recording densities of 100 Tb/inch². However, a problem with these materials is the high coercivity of these L1₀ films, which exceeds 2 T, making them difficult to switch.

Another problem is when the isolated islands are as small as a single magnetic domain, the magnetization reversal takes place through coherent rotation. The minimum coercivity in this case is half the anisotropy field, Hₐ=2Kᵤ/μ₀Mₛ, where Kᵤ is the uniaxial anisotropy of the island and Mₛ is the saturation magnetization of the medium at 45 degrees. Methods to facilitate switching in these alloys include exchange-coupled media, in which a soft magnetic material is used as a buffer layer for the hard L1₀ alloy, and heat assisted magnetic recording, where the high coercivity of the bits is temporarily reduced by heating the medium with a laser pulse, an approach originally used in magneto-optical recording. A recording density of 1 Tb/inch² has been demonstrated in BPM using a plasmonic antenna to focus a laser beam onto 12 nm bits.

UK Patent publication number GB1405119, IBM, discloses MnAlGe, MnGaGe and several other derivatives of these alloys with perpendicular magnetization. These materials crystallize in Cu₂Sb structure and exhibit low magnetization and low anisotropy.

Japanese patent publication number JP1042040, IBM, discloses multi-layers of Mn_{1-x-y}AₓD_{y} ternary alloy thin films deposited in multilayer form, where 0.1≦x≦0.6, and 0.1≦y≦0.6. However this structure exhibits poor magnetic properties.

Japanese patent publication number JP6184005, Victor Company of Japan, discloses a magnetic material composed of a ternary alloy of Mn, Al and Ge, which crystallizes in the Cu₂Sb structure.

U.S. Pat. No. 5,374,472, Krishnan, discloses a high anisotropy δ-Mn₁₋ₓGaₓ (x=0.4±0.05) magnetic material that crystallizes in the CuAu (L1₀) structure, however the material does not provide very high anisotropy in addition to its high magnetization.

US patent publication number US2009080239A1, Nagase, discloses a memory device which utilizes a perpendicular recording layer that contains Co₂XY, where X can be Mn and Y can be Ga. Co₂XY alloys are cubic and exhibit in-plane anisotropy, but can be made perpendicular through exchange coupling between Co₂XY and perpendicular magnetic layer; the recording layer then behaves like a single perpendicular layer. However the material does not provide high anisotropy combined with high magnetization.

It is the object of the present invention to provide a material to overcome at least some of the above-referenced problems.

### SUMMARY OF THE INVENTION

According to the present invention there is provided, as set out in the appended claims, a magnetic recording medium for use in storing information, the medium comprising the use of a Manganese-Gallium alloy. More specifically, in one embodiment there is provided a magnetic recording medium comprising:
a substrate having a surface upon which is placed a magnetic recording layer, wherein the magnetic recording layer comprises a Manganese-Gallium alloy material with uni-axial anisotropy, said alloy material having a D0₂₂ unit cell crystalline structure.

The technical problem that has been solved is the development of a magnetic recording medium which allows a much higher areal density than 1 Terabit/inch², the theoretical upper limit of the currently used continuous perpendicular media (for example, hard disk drives (HDD)). Platinum (Pt) is the commonly used material that provides high anisotropy for the process of manufacturing the current HDD. Pt is 100 times more expensive than Gallium. The film coercivity of the present invention is lower than that of the potential Cobalt-Platinum (CoPt) and Iron-Platinum (FePt) counterparts, which makes it easier to write to. The bit thermal stability should be comparable. While the anisotropy of tetragonal Mn₂Ga is not as high as the L1₀ structure CoPt and FePt, it is quite sufficient to allow bit patterned media with areal densities up to 10 Terabit/inch² with 10 year thermal stability, at a significantly lower cost compared to the Pt containing alloys. Moreover, the single crystalline order can be obtained at much lower temperatures compared to the ordering temperature of L1₀ alloys, which can lower the overall growth cost.

A unique feature of the invention is the discovery that a much higher saturation magnetization of 470 emu/cc (kA/m) was achieved in Mn₂Ga that crystallizes in a variant of the D0₂₂ tetragonal structure as shown in FIG. 1a. In the following embodiments D0₂₂ is to be understood as both fully occupied D0₂₂ unit cell as well as under-stoichiometric compositions of MnₓGa (1.9≦x≦3.0).

In one embodiment the D0₂₂ unit cell comprises 2 Gallium atoms and between 3.8 to 6 Manganese atoms.

In one embodiment the Manganese-Gallium alloy material comprises a magnetic property with a unique magnetic easy axis that is normal to the substrate.

In one embodiment the Manganese-Gallium alloy material comprises one or more magnetic atoms with magnetic moments pointing normal to the substrate.

In one embodiment the substrate surface comprises a plurality of spaced apart magnetic elements or bits.

In one embodiment the Manganese-Gallium (Mn—Ga) alloy consists of thin films of a MnₓGa alloy where 1.9≦x≦3.0.

In one embodiment, wherein when x=2 the magnetic recording layer comprises thin films of epitaxial tetragonal Mn₂Ga which exhibit an anisotropy constant (Kᵤ) of approximately 2.35 MJ m⁻³.

In one embodiment the magnetic recording layer has a magnetization (Mₛ) of approximately 470 kA m⁻¹ and an anisotropy field (μ₀Hₐ) of approximately 10 T.

In one embodiment, the substrate may be selected from MgO (001), STO (001), Cr (001) or any combination of substrate adapted to allow epitaxial growth of said material. It will be appreciated that other substrates could be engineered to facilitate the epitaxial growth of Mn₂Ga, provided that the lattice mismatch is not more than 10%. The epitaxial growth can take place in either cube on cube mode (the case for MgO (001) substrate) or, through a 45 degree rotation (Cr (001) substrate case). For example the lattice parameter of Cr is a=288 pm, therefore a√2=407 pm, which is close to a=394 pm of Mn₂Ga.

In one embodiment the substrate further comprises a seed layer.

In one embodiment the magnetic recording layer comprises a lattice structure.

In another embodiment there is provided a method for producing a magnetic recording medium comprising the steps of:
(a) providing a substrate having a surface; and
(b) forming a magnetic recording layer, comprising of a Manganese-Gallium (Mn—Ga) alloy material, on said surface.

In one embodiment the Manganese-Gallium alloy consists of thin films of a MnₓGa alloy where 1.9≦x≦3.0 and having an anisotropy constant of Kᵤ=2.35 MJ m⁻³.

In one embodiment in the step (b) further comprises forming a plurality of spaced apart magnetic elements or bits on the surface in a patterned array on the surface at a density up to 10 Tb/inch².

In one embodiment the magnetic elements are grown on the substrate in a high vacuum chamber with a base pressure of 2×10⁻⁸ Torr and are sputtered from a Mn—Ga target (3N purity) at substrate temperatures (T_{S}) of between 250-450° C.

In one embodiment the substrate temperature Tₛ=360° C.

In one embodiment the sputtering pressure during deposition is between 4 to 8 mTorr and the growth rate is between 0.5 to 1.5 nm/minute.

In a further embodiment, there is provided a substantially tetragonal D0₂₂ Manganese-Gallium thin film alloy for use as a magnetic recording medium.

In another embodiment there is provided a magnetic recording medium comprising a substrate having a surface upon which is placed a magnetic recording layer, wherein the magnetic recording layer comprises a Manganese-Gallium alloy material with uniaxial anisotropy.

### BRIEF DESCRIPTION OF THE DRAWINGS

The invention will be more clearly understood from the following description of an embodiment thereof, given by way of example only, with reference to the accompanying drawings, in which:

FIG. 1 illustrates schematics of (a) the D022 structure according to a preferred embodiment of the invention and (b) L2₁ unit cells of Mn₃Ga. Ga atoms are positioned in a body-centered tetragonal structure and Mn atoms occupy 2b and 4d Wyckoff positions;

FIG. 2 illustrates (a) 2-theta scans of epitaxial Mn₂Ga films grown at various substrate temperatures. The data are offset in y-axis for better comparison. Atomic force micrographs of a 10 nm granular film (b) and a 66 nm film (c), scale bars are 1 μm; and

FIG. 3 illustrates (a) Room temperature magnetization curve for Mn₂Ga sample with magnetic field applied perpendicular to and parallel to the sample surface grown at 360° C. The inset shows the variation of coercivity with the film thickness. (b) Variation of magnetization, coercivity and anisotropy constant vs. the growth temperature Tₛ.

### DETAILED DESCRIPTION OF THE DRAWINGS

This invention utilizes thin films of epitaxial tetragonal D022-Mn2Ga, which can serve as a new medium for high-density perpendicular recording. Alloys in the MnxGa (1.9≦x≦3.0) range have two stable phases. The bulk material is easily obtained by arc melting in a variant of the hexagonal D019 structure, which is either antiferromagnetic or weakly ferromagnetic. The tetragonal phase, which is a variant of the tetragonal D022 structure, can then be obtained by annealing the hexagonal material at 350-400° C. for 1-2 weeks.

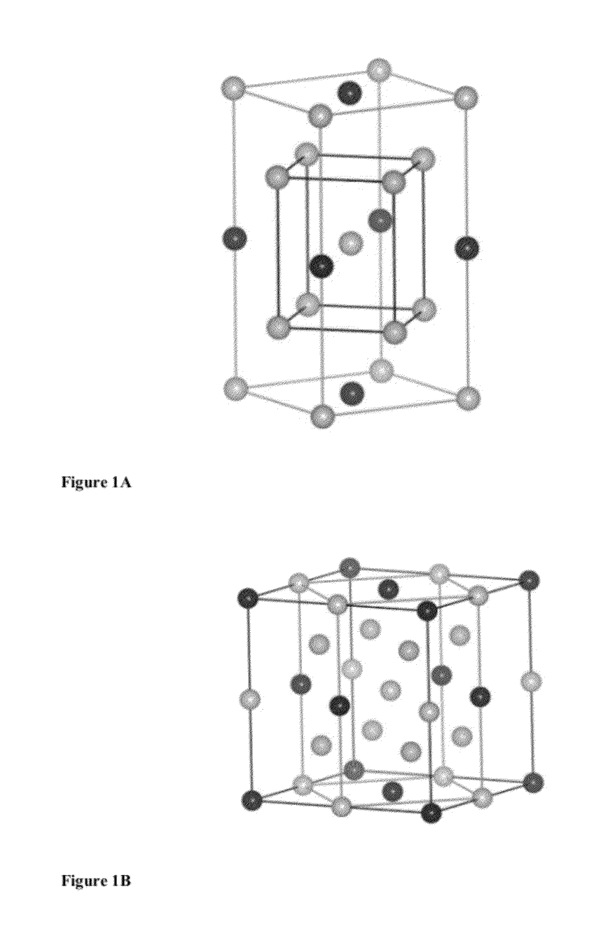

Referring now to FIG. 1, the D022 structure (FIG. 1a) can be viewed as a variant of L21 cubic Heusler structure (FIG. 1b) that is stretched along c-axis by ˜28%, which leads to high uniaxial anisotropy. The magnetic structure shown in FIG. 1a is basically a magnetic recording layer shown at the atomic scale shown as a tetragonal D0₂₂ structure, according to a preferred embodiment of the invention. In this geometry, Ga atoms order in a body-centered tetragonal structure and Mn atoms are positioned in 2b and 4d Wyckoff positions. In Mn₂Ga, some of the Mn atoms are deficient in the D0₂₂ unit cell, which leads to a slight increase in the unit cell volume and the density is ˜25% lower than Mn₃Ga. The Curie temperature of the tetragonal Mn₂Ga may be greater than 730K, at which the material undergoes a structural phase change. Mn₂Ga material crystallizes in a variant of the D0₂₂ crystal structure. The full D0₂₂ crystal structure is composed of Mn₃Ga as shown in FIG. 1a. In Mn₃Ga the unit cell is defined by a body-centered tetragonal structure formed by Ga atoms (light grey atoms), and Mn atoms occupies 2b and 4d Wyckoff positions. Removing one of the Mn atoms in Mn₃Ga that couple antiferromagnetically to the other Mn atoms thereby increases the magnetization.

The Mn atoms occupy two different crystal lattice sites, which produce an antiferromagnetic coupling between the two sites. This creates a ferrimagnetic material with low magnetization. Mn₂Ga is obtained by removing one of the Mn atoms from this structure. The removal of one Mn atom does not alter the crystal structure. The only structural change in the material is a slight expansion of the unit cell along the c-axis. However, because of the removal of an anti-ferromagnetically coupling Mn atom the magnetization is greatly enhanced while maintaining the anisotropy sufficiently high. The material can be grown by dc-magnetron sputtering on heated substrates/seed layers with lattice matching.

Tetragonal Mn₂Ga thin films can be grown on MgO (001) and STO (001) substrates (or any other seed layer having a lattice parameter that is close to or similar to the lattice parameter a of Mn₂Ga in a high vacuum chamber with a base pressure of 2×10⁻⁸ Torr. It will be appreciated that Cr (001) seedlayers can be used as an alternative, and Pt (001) and Pd (001) seedlayers can also be used but these are very expensive. Ag (001), Au (001) and Al (001) also have lattice parameters very close to Mn₂Ga and could also be suitable. In principle, their intermetallic alloys could also be used as seedlayers. The Mn₂Ga films can be sputtered from a stoichiometric Mn₂Ga target (3N purity) at substrate temperatures Tₛ=250-450° C. The sputtering pressure during deposition can be 6 mTorr and the growth rate is ˜1 nm/min. All films exhibit perpendicular anisotropy (c-axis normal to plane) regardless of Tₛ. Structural characterization can be carried out using X-ray diffraction with a Cu Kα₁ monochromated parallel beam. The lattice parameters measured by reciprocal space mapping are a=394 pm and c=713 pm (c/a=1.8). The high c/a ratio leads to high perpendicular anisotropy, i.e. c-axis being the magnetic easy axis.

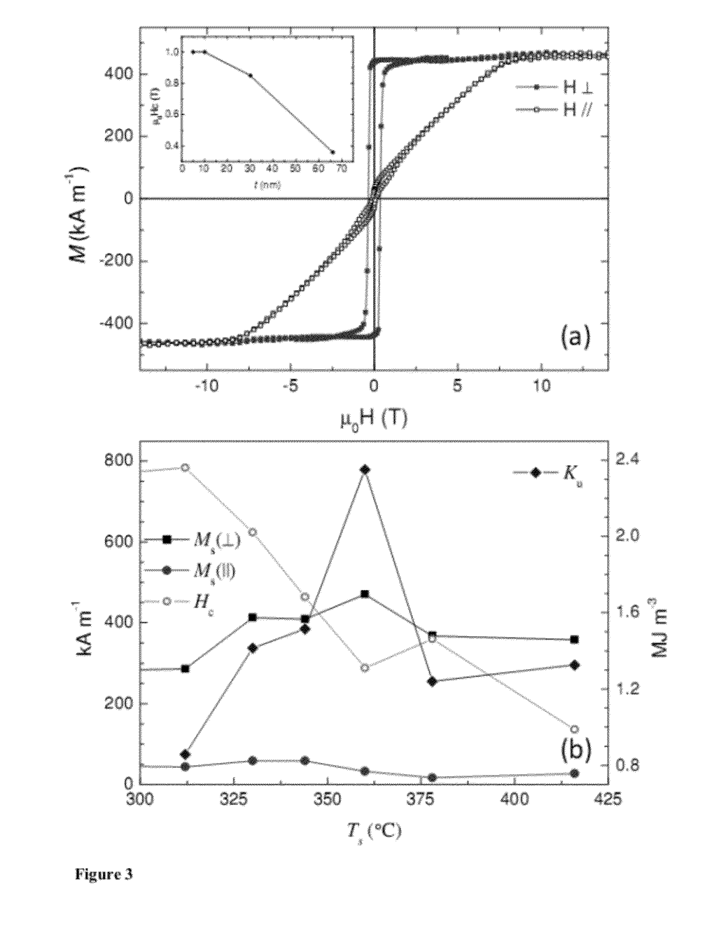

Despite the large lattice mismatch between Mn₂Ga and MgO (6.9%), epitaxial growth can take place at elevated temperatures. The crystallinity of the films improves with increasing Tₛ but the magnetization increases only up to Tₛ=360° C. The thin films crystallize in a variant of D0₂₂ tetragonal structure with c-axis normal to the plane. Magnetization in Mn alloys depends strongly on Mn—Mn separation, which is influenced by the crystallinity and local atomic order. The highest room temperature magnetization Mₛ=470 kA m⁻¹ and anisotropy field μ₀Hₐ=10 T can be obtained for films grown at 360° C. (FIG. 3a). The anisotropy constant Kᵤ deduced from the magnetization and anisotropy field is 2.35 MJ m⁻³ The coercivity of a 66 nm thick film with the highest anisotropy is 0.36 T, which increases with decreasing thickness and reaches 1 T for 5-10 nm films as shown in FIG. 3a inset.

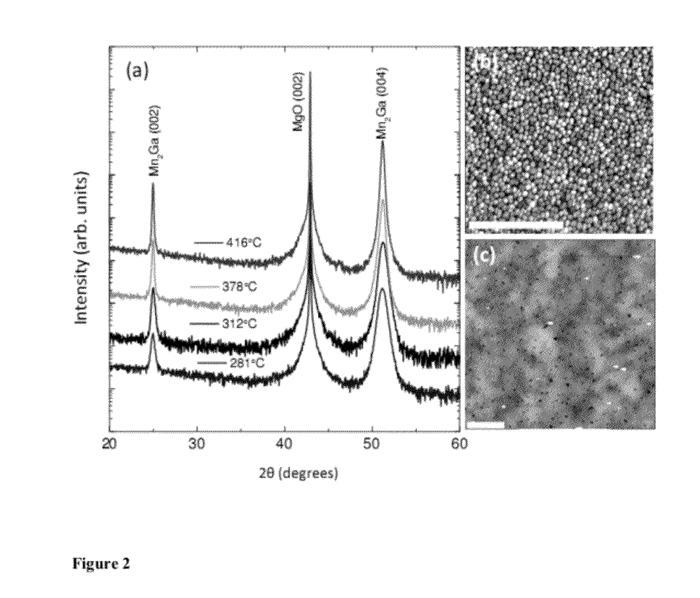

FIG. 2 illustrates (a) 2-theta scans of epitaxial Mn₂Ga films grown at various substrate temperatures. The data are offset in y-axis for better comparison. Atomic force microscopy confirms that 10 nm and 66 nm films are granular and continuous respectively with a Root Mean Square (rms) roughness of ˜1.5 nm (FIG. 2b-2c), making the films suitable for large area patterning. The variation of magnetization, coercivity and uniaxial anisotropy constant is shown in FIG. 3b. As the substrate temperature increases the coercivity decreases but the magnetization and anisotropy constant peaks at Tₛ=360° C. The growth temperature dependence of the coercivity and magnetization show that the magnetic properties can be engineered to suit specific requirements. The in-plane magnetization data also reveals a small canted magnetic moment, which tends to be smaller for the films with higher perpendicular magnetization. The in-plane moment could be due to magnetic frustration as a result of site disorder. It may facilitate switching in the thin granular films, where the coercivity is much less than the anisotropy field.

The highest magnetization in the tetragonal MnₓGa 1.9≦x≦3.0 series is obtained in Mn₂Ga. In the epitaxial thin films of the present invention, a higher magnetization was measured when compared to the bulk samples.

A high magnetization combined with high anisotropy is achieved in the Mn₂Ga alloy thin films grown at Tₛ=360° C. The high uniaxial anisotropy of Kᵤ=2.35 MJ m⁻³ can support 10-year thermal stability condition (KᵤV/k_{B}T≧60) using V=100 nm³ bits, which can allow areal densities up to 10 Tb/inch² in BPM.

Recent developments in nanoimprint lithography, combined with directed block co-polymer lithography promise reliable fabrication of high density media at low cost. Thermally assisted recording using high anisotropy perpendicular materials is a promising technology for high density recording. Although very high anisotropy L1₀ structure CoPt and FePt offer extremely high recording density, they crystallize at much higher temperatures (˜700° C.) and the high Pt content increases the overall cost. Tetragonal Mn₂Ga presented here should allow high density recording up to 10 Tb/inch² with 10-year stability using much cheaper materials.

In addition to bit patterned media, it will be appreciated that the magnetic recording medium of the present invention will have applications in continuous media, spin valves, magnetic memory elements, permanent magnets and spin light emitting diodes (spin-LEDs).

In another embodiment of the present invention some of the manganese atoms can be replaced by Ferrous (Iron) atoms such that the structure can still be used as a magnetic recording medium without affecting performance of operation.

In the specification, the term “areal density” should be understood to mean the amount of data that can be stored in a given amount of hard disk platter (the disk upon which information is stored). Disk platters surfaces are two-dimensional, and areal density is a measure of the number of bits that can be stored in a unit of area. Areal density is usually expressed in bits per square inch (BPSI).

In the specification, the term “coercivity” of a ferromagnetic material, or coercive force, should be understood to mean the intensity of the applied magnetic field required to reduce the magnetization of that material to zero after the magnetization of the sample has been driven to saturation.

In the specification, the term “magnetization” should be understood to mean the quantity of magnetic moment per unit volume, and is defined as:

$$M = \frac{{Σ}_{i} {N}_{i} {m}_{i}}{V}$$

where Nᵢ is the number of magnetic atoms in site i and mᵢ equals the magnetic moment of each magnetic atom at site i. The M-field is measured in amperes per meter (A/m) in SI units.

In the specification the terms “comprise, comprises, comprised and comprising” or any variation thereof and the terms “include, includes, included and including” or any variation thereof are considered to be totally interchangeable and they should all be afforded the widest possible interpretation and vice versa.

The invention is not limited to the embodiments hereinbefore described but may be varied in both construction and detail.

1. A magnetic recording medium comprising:
a substrate having a surface upon which is placed a magnetic recording layer, wherein the magnetic recording layer comprises a Manganese-Gallium alloy material with uni-axial anisotropy, said alloy material having a D0₂₂ unit cell crystalline structure.

2. A magnetic recording medium according to claim 1, wherein the D0₂₂ unit cell comprises 2 Gallium atoms and between 3.8 to 6 Manganese atoms.

3. The magnetic recording medium according to claim 1, wherein the Manganese-Gallium alloy material comprises a magnetic property with a unique magnetic easy axis that is normal to the substrate.

4. A magnetic recording medium according to claim 1, wherein the Manganese-Gallium alloy material comprises one or more magnetic atoms with magnetic moments pointing normal to the substrate.

5. A magnetic recording medium according to claim 1, wherein the substrate surface comprises a plurality of spaced apart magnetic elements or bits.

6. A magnetic recording medium according to claim 1, wherein the Manganese-Gallium (Mn—Ga) alloy consists of thin films of a MnₓGa alloy where 1.9≦x≦3.0.

7. A magnetic recording medium according to claim 1, wherein the Manganese-Gallium (Mn—Ga) alloy consists of thin films of a MnₓGa alloy where x=2 the magnetic recording layer comprises thin films of epitaxial tetragonal Mn₂Ga which exhibit an anisotropy constant (Kᵤ) of approximately 2.35 MJ m⁻³.

8. A magnetic recording medium according to claim 1, wherein the magnetic recording layer has a magnetization (Mₛ) of approximately 470 kA m⁻¹ and anisotropy field (μ₀Hₐ) of approximately 10 T.

9. A magnetic recording medium according to claim 1, wherein the substrate is selected from one or more to the following: MgO (001), STO (001), Cr (001), Ag (001), Au (001), Al (001), or any combination of seed-layers and substrates adapted to allow c-axis epitaxial growth of said material.

10. A magnetic recording medium according to claim 1, wherein the substrate further comprises a seed layer.

11. A magnetic recording medium according to claim 1 wherein the magnetic recording layer comprises a lattice structure.

12. A method for producing a magnetic recording medium comprising the steps of:
(a) providing a substrate having a surface; and
(b) forming a magnetic recording layer, comprising of the Manganese-Gallium (Mn—Ga) alloy material in its D0₂₂ crystal structure, on said surface.

13. A method according to claim 12, wherein the Manganese-Gallium alloy material comprises a magnetic property with a unique magnetic easy axis that is normal to the substrate.

14. A method according to claim 12, wherein the Manganese-Gallium alloy material comprises one or more magnetic atoms with magnetic moments pointing normal to the substrate.

15. A method according to claim 12, wherein the Manganese-Gallium alloy consists of thin films of a MnₓGa alloy where 1.9≦x≦3.0 and having an anisotropy constant of Kᵤ=2.35 MJ m⁻³.

16. A method according to any of claim 12, wherein in the step (b) comprises forming a plurality of spaced apart magnetic elements or bits on the surface in a patterned array on the surface at a density up to 10 Tb/inch².

17. A method according to claim 12, wherein magnetic elements are grown on the substrate in a high vacuum chamber with a base pressure of 2×10⁻⁸ Torr and are sputtered from a Mn—Ga target (3N purity) at substrate temperatures (Tₛ) of between 250-450° C.

18. A method according to claim 12, wherein magnetic elements are grown on the substrate in a high vacuum chamber with a base pressure of 2×10⁻⁸ Torr and are sputtered from a Mn—Ga target (3N purity) at substrate temperature (Tₛ) of approximately 360° C.

19. A method according to claim 12, wherein the sputtering pressure during deposition is between 4 to 8 mTorr and the growth rate is between 0.5 to 1.5 nm/minute.

20. A substantially tetragonal Manganese-Gallium thin film alloy with a magnetic anisotropy field greater than 6 Tesla for use as a magnetic recording medium.

21. The tetragonal Manganese-Gallium thin film alloy as claimed in claim 20 wherein said alloy material comprises a D0₂₂ crystalline structure.
